(19) United States
(12) Patent Application Publication
(10) Pub. No.: US 2017/0146582 A1
(43) Pub. Date: May 25, 2017

(54) TEST DEVICE AND METHOD FOR DISPLAY PANEL

(71) Applicant: Shenzhen Chia Star Optoelectonics Technology Co., Ltd., Shenzhen, Guangdong (CN)

(72) Inventor: Yanfeng FU, Shenzhen (CN)

(73) Assignee: Shenzhen Chia Star Optoelectonics Technology Co., Ltd., Shenzhen, Guangdong (CN)

(21) Appl. No.: 14/775,548

(22) PCT Filed: Aug. 20, 2015
(86) PCT No.: PCT/CN2015/087700

§ 371 Date: Sep. 11, 2015

(30) Foreign Application Priority Data
Apr. 20, 2015 (CN) 201510198398.9

(51) Int. Cl. G01R 31/02; G09G 3/00; G01R 31/28

(52) U.S. Cl. CPC G01R 31/025; G01R 31/2825; G09G 3/006

(57) ABSTRACT

The present invention teaches a test device for a display panel which contains a signal transmission module, a first single reception module, and a second signal reception module. The signal transmission module transmits a test signal along a first conductive line in an active area and along a second conductive line in a fan-out area of the display panel simultaneously. The first and second signal reception modules detect the test signal on the first and second conductive line, respectively, so as to determine their conductivity. The present invention also teaches a test method for a display panel. By adding the second signal reception module in the fan-out area of the display panel, the present invention is able to effectively locate a faulty conductive line in the fan-out area where repair can be conducted. The yield of the display panel is as such enhanced.

### BACKGROUND OF THE INVENTION

1. Field of the Invention

The present invention relates to display techniques, and in particular to a device and a related method for testing a display panel.

2. The Related Arts

Panels of thin-film-transistor liquid crystal display (TFT LCD), especially those of large dimensions, require sophisticated production process. After production, the panels have to be tested for open circuit and short circuit, and then repaired if necessary, so as to maintain the yield of the panel production.

A TFT LCD panel contains a large number of parallel conductive lines, usually including gate lines and data lines. Due to residual metals or particles, some of these conductive lines may be open-circuited or short-circuited, and have to be tested to locate these defects. FIG. 1 is a schematic diagram showing a conventional testing device 10 working on a display panel 20. As illustrated, the testing device 10 contains a signal transmission module 101 and a signal reception module 102. The testing device 10 then scans each line on the display panel 20 so as to locate faulty lines.

As shown in FIG. 1, the display panel 20 contains an active area AA and fan-out areas FAs. The lines (e.g., gate lines 201 and data lines 202) on the display panel 20 are formed both within the active area AA and the fan-out areas FAs. The transmission and reception modules 101 and 102 are both positioned at the active area AA's edges. Faulty lines within the fan-out areas FAs as such cannot be detected, therefor adversely affecting the display panel's production yield and causing unnecessary waste.

### SUMMARY OF THE INVENTION

To obviate the shortcoming of the prior art, the present invention provides a test device for a display panel, which contains a signal transmission module, a first single reception module, and a second signal reception module. The signal transmission module transmits a test signal along a first conductive line in an active area and along a second conductive line in a fan-out area of the display panel simultaneously. The first and second signal reception modules detect the test signal on the first and second conductive line, respectively, so as to determine their conductivity.

More specifically, the signal transmission module is slidable so as to transmit the test signal line-by-line along each first conductive line in the active area and along each second conductive line in the fan-out areas.

More specifically, the first signal reception module is slidable so as to detect the test signal line-by-line on each first conductive line in the active area.

More specifically, the second conductive lines in the fan-out area are short-circuited together and jointly connected to the second signal reception module.

More specifically, the second signal reception module is slidable so as to detect the test signal line-by-line on each second conductive line in the fan-out area.

The present invention also teach a test method for a display panel, which contains the steps: transmitting a test signal along a first conductive line in an active area and along a second conductive line in a fan-out area of the display panel simultaneously through a signal transmission module; detecting the test signal on the first conductive line so as to determine the conductivity of the first conductive line through a first signal reception module; and detecting the test signal on the second conductive line so as to determine the conductivity of the second conductive line through a second signal reception module.

More specifically, the signal transmission module is slidable so as to transmit the test signal line-by-line along each first conductive line in the active area and along each second conductive line in the fan-out areas.

More specifically, the first signal reception module is slidable so as to detect the test signal line-by-line on each first conductive line in the active area.

More specifically, the second conductive lines in the fan-out area are short-circuited together and jointly connected to the second signal reception module.

More specifically, the second signal reception module is slidable so as to detect the test signal line-by-line on each second conductive line in the fan-out area.

By adding the second signal reception module in the fan-out area of the display panel, the present invention is able to effectively locate a faulty conductive line in the fan-out area and repair can be subsequently conducted so as to enhance the yield of the display panel.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic diagram showing a conventional testing device working on a display panel;

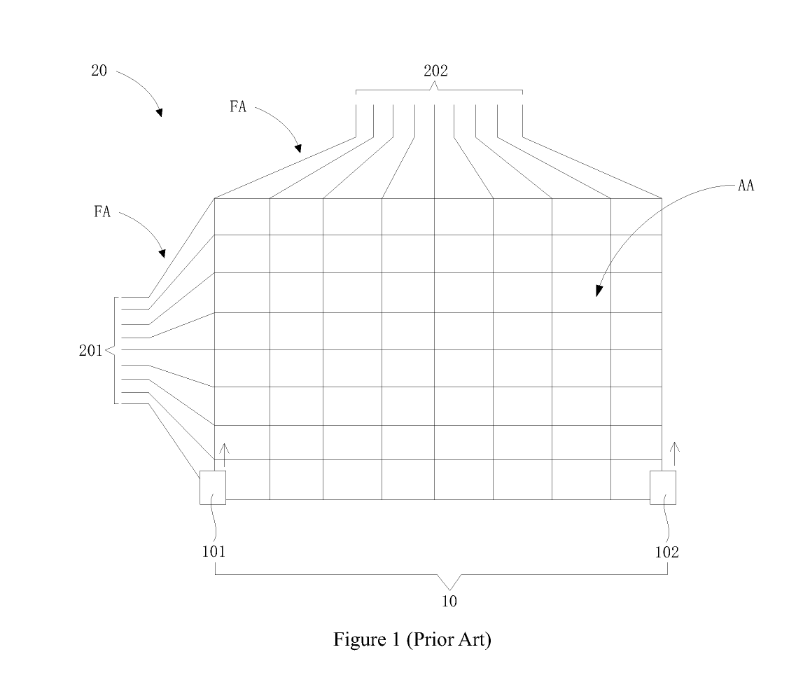

FIG. 2 is a schematic diagram showing a test device according to an embodiment of the present invention in testing a display panel; and

FIG. 3 is a schematic diagram showing a test device according to another embodiment of the present invention in testing a display panel.

### DETAILED DESCRIPTION OF THE PREFERRED EMBODIMENTS

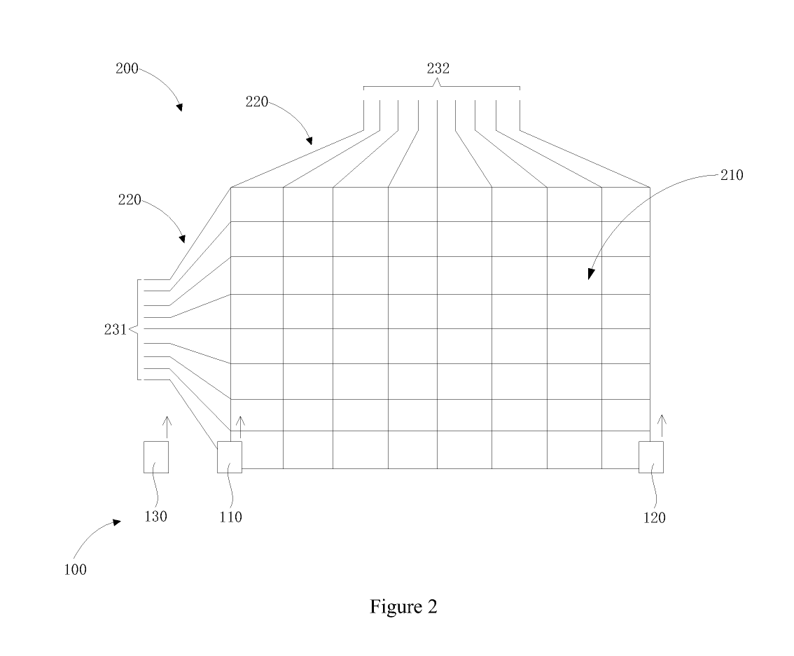

FIG. 2 is a schematic diagram showing a test device 100 according to an embodiment of the present invention in testing a display panel 200. As illustrated, the test device 100 contains at least a signal transmission module 110, at least a first signal reception module 120, and at least a second signal reception module 130. In alternative embodiments, there can be two or more signal transmission modules 110, first signal reception modules 120, and second signal reception modules 130. FIG. 2 shows a single signal transmission module 110, a single first signal reception module 120, and a single second signal reception module 130 as example.

The display panel 200 which can be a liquid crystal display (LCD) panel or an organic light emitting diode (OLED) display panel. The present invention does not specify the type of display panels that can be tested by the test device 100. The display panel 200 contains an active area 210, fan-out areas 220 outside the active area 210, and the parallel conductive lines within the active and fan-out areas 210 and 220. The conductive lines contains gate lines 231 arranged along a vertical direction and extended along a lateral direction, and data lines 232 arranged along the lateral direction and extended along the vertical direction.

The signal transmission module 110 transmits a test signal along a conductive line (gate line 231 or data line 232) in the active area 210 and a conductive line in a fan-out area 220 simultaneously. The signal transmission module 110 can be slidable so that it can test line-by-line the conductive lines in the active and fan-out areas 210 and 220.

The first signal reception module 120 is for receiving the test signal from and thereby testing the conductivity of conductive lines within the active area 210. For example, if the first signal reception module 120 receives the test signal on a conductive line in the active area 210 from the signal transmission module 110, the conductive line is conducting. In contrast, if the first signal reception module 120 does not receive the test signal on a conductive line in the active area 210 from the signal transmission module 110, the conductive line is defective (e.g., open-circuited).

Additionally, the first signal reception module 120 can also be slidable. In FIG. 2, an exemplary arrow pointing upward indicates the sliding direction. As such, the first signal reception module 120 can work with the signal transmission module 110 to test line-by-line the conductive lines in the active area 210.

The second signal reception module 130 is for receiving the test signal from and thereby testing the conductivity of conductive lines within a fan-out area 220. For example, if the second signal reception module 130 receives the test signal on a conductive line in a fan-out area 220 from the signal transmission module 110, the conductive line is conducting. In contrast, if the second signal reception module 130 does not receive the test signal on a conductive line in the fan-out area 210 from the signal transmission module 110, the conductive line is defective (e.g., open-circuited).

Additionally, the second signal reception module 130 can also be slidable. As such, the second signal reception module 130 can work with the signal transmission module 110 to test line-by-line the conductive lines in the fan-out area 220.

Please note that, in FIG. 2, the second signal reception module 130 is applied to test the conductivity of gate lines 231. It should be understood that, to test the data lines 232, all is required is to move the second signal reception module 130 to where the data lines 232 are located.

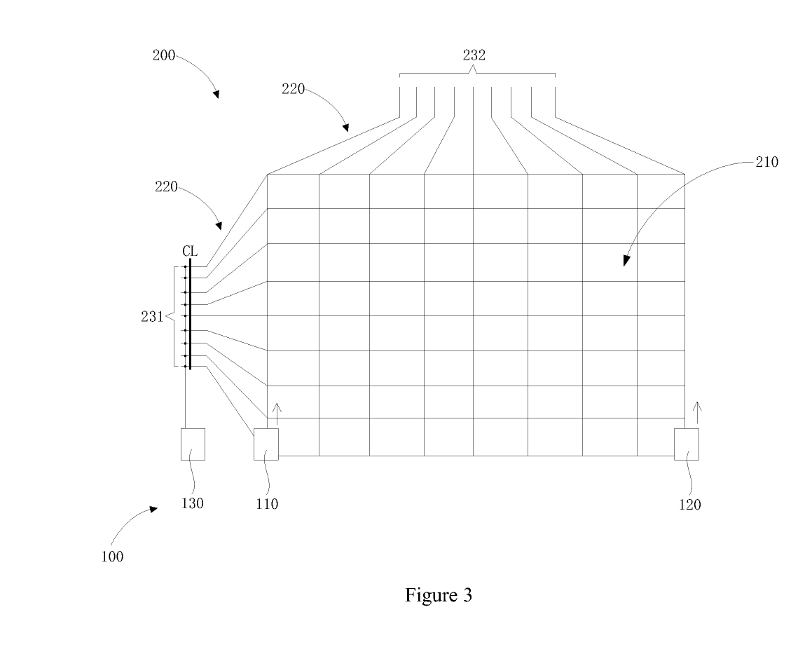

FIG. 3 is a schematic diagram showing a test device 100 according to another embodiment of the present invention in testing a display panel 200. What is different from the previous embodiment is that the second signal reception module 130 is immobile in the present embodiment, and the conductive lines in a fan-out area 220 are short-circuited together and then jointly connected to the second signal reception module 130. Please note that, after testing, the short-circuited part of the conductive lines in the fan-out area 220 is removed by cutting along an imaginary line denoted as “CL” in FIG. 3, and the conductive lines will be independent and separated from each other as before testing.

As describe above, by adding the second signal reception module 130 in the fan-out areas 220 of the display panel 200, the test device 100 is able to effectively locate a faulty conductive line in the fan-out areas 220. If necessary, repair can be conducted so as to enhance the yield of the display panel 200.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A test device for a display panel, comprising a signal transmission module, a first single reception module, and a second signal reception module, wherein
the signal transmission module transmits a test signal along a first conductive line in an active area and along a second conductive line in a fan-out area of the display panel simultaneously;
the first signal reception module detects the test signal on the first conductive line so as to determine the conductivity of the first conductive line; and
the second signal reception module detects the test signal on the second conductive line so as to determine the conductivity of the second conductive line.

2. The test device as claimed in claim 1, wherein the signal transmission module is slidable so as to transmit the test signal line-by-line along each first conductive line in the active area and along each second conductive line in the fan-out areas.

3. The test device as claimed in claim 2, wherein the first signal reception module is slidable so as to detect the test signal line-by-line on each first conductive line in the active area.

4. The test device as claimed in claim 3, wherein the second conductive lines in the fan-out area are short-circuited together and jointly connected to the second signal reception module.

5. The test device as claimed in claim 3, wherein the second signal reception module is slidable so as to detect the test signal line-by-line on each second conductive line in the fan-out area.

6. A test method for a display panel, comprising the steps of:
transmitting a test signal along a first conductive line in an active area and along a second conductive line in a fan-out area of the display panel simultaneously through a signal transmission module;
detecting the test signal on the first conductive line so as to determine the conductivity of the first conductive line through a first signal reception module; and
detecting the test signal on the second conductive line so as to determine the conductivity of the second conductive line through a second signal reception module.

7. The test method as claimed in claim 6, wherein the signal transmission module is slidable so as to transmit the test signal line-by-line along each first conductive line in the active area and along each second conductive line in the fan-out areas.

8. The test method as claimed in claim 7, wherein the first signal reception module is slidable so as to detect the test signal line-by-line on each first conductive line in the active area.

9. The test method as claimed in claim 8, wherein the second conductive lines in the fan-out area are short-circuited together and jointly connected to the second signal reception module.

10. The test method as claimed in claim 8, wherein the second signal reception module is slidable so as to detect the test signal line-by-line on each second conductive line in the fan-out area.
